(19) United States
(12) Patent Application Publication
(10) Pub. No.: US 2024/0162363 A1
(43) Pub. Date: May 16, 2024

(54) Solar cell structure

(71) Applicant: Chi Hui Chang, Taichung, Taiwan (TW)

(72) Inventor: Chi Hui Chang, Taichung, Taiwan (TW)

(21) Appl. No.: 18/216,639

(22) Filed: Jun. 30, 2023

(51) Int. Cl. H01L 31/055; H01L 31/0468

(52) U.S. Cl. CPC H01L 31/055; H01L 31/0468

(57) ABSTRACT

A solar cell structure includes a first surface on a top, the first surface including, from top to bottom, a power conversion efficiency increase layer, a glass layer, a first sealing layer, a photovoltaic effect junction, a second sealing layer, and a back layer; a second surface on a bottom, and a peripheral surface formed around the first surface and the second surface. The power conversion efficiency increase layer includes a transparent material and a plurality of conducting carbon materials mixed with a plurality of fluorescent materials in the transparent material. The fluorescent materials are nanometer scales.

### BACKGROUND OF THE INVENTION

### 1. Field of the Invention

The invention relates to solar cells and more particularly to a solar cell structure capable of increasing photovoltaic effect.

### 2. Description of Related Art

Due to the increasingly serious environmental problems such as energy shortage and greenhouse effect, various countries have actively researched and developed various alternative energy sources, especially the solar power generation as green energy, which has attracted the most attention. A solar cell is an electronic device and typically comprises a junction formed between p-type and n-type conductivity regions in a semiconductor body. The solar cell converts the energy light into electricity by the photovoltaic effect.

However, the power conversion efficiency of the typical solar cells is not ideal. For the widely used crystalline silicon solar cells, the power conversion efficiency thereof is about 15%. The reason is that the energy distribution of the sunlight spectrum is divided into three blocks in which visible light accounts for about 47% and ultraviolet light and infrared light account for about 53%. Thus, it only converts 15% of sunlight into usable electrical energy, and the remaining 85% of sunlight become useless heat. Therefore, the development direction of the conventional solar cells is to increase power conversion efficiency. For example, there are sun-tracking typed solar panels that track the optimum sunlight position to increase light collection. However, the light concentration type solar panel incorporating the solar cells are complex in structure, heavy in weight, difficult to assemble, and require regular maintenance, resulting in a substantial increase in the production cost.

III-V multi-junction solar cells having direct bandgap feature are advantageous due to high light absorption rate, high power conversion efficiency, thin film, and stability at high temperature operations. However, the solar cells have complex manufacturing processes, reduced process yields, and increased manufacturing costs.

It is understood that the higher the temperature of the working environment, the lower the power conversion efficiency. A previous study pointed out that for every 1 degree Celsius increase in temperature, the average power generation of solar cells decreases by 0.45%. High temperature not only decreases power generation of a solar cell but also shortens the useful life thereof. In short, the conventional solar cells cannot increase the ratio of converting sunlight into usable electrical energy.

Thus, the need for improvement still exists.

### SUMMARY OF THE INVENTION

It is therefore one object of the invention to provide a solar cell structure comprising a first surface on a top, the first surface including, from top to bottom, a power conversion efficiency increase layer, a glass layer, a first sealing layer, a photovoltaic effect junction, a second sealing layer, and a back layer; a second surface on a bottom, and a peripheral surface formed around the first surface and the second surface; wherein the power conversion efficiency increase layer includes a transparent material and a plurality of conducting carbon materials mixed with a plurality of fluorescent materials in the transparent material; wherein the fluorescent materials are micrometer scales or nanometer scales; and wherein the transparent material is thermoplastic.

The above and other objects, features and advantages of the invention will become apparent from the following detailed description taken with the accompanying drawings.

### BRIEF DESCRIPTION OF THE DRAWINGS

FIG. 1 is a perspective view of a solar cell structure according to a first preferred embodiment of the invention;

FIG. 2 is an exploded view of the solar cell structure;

FIG. 3 is a longitudinal sectional view of the solar cell structure;

FIG. 4 is a longitudinal sectional view of a solar cell structure according to a second preferred embodiment of the invention;

FIG. 5 is a longitudinal sectional view of a solar cell structure according to a third preferred embodiment of the invention;

FIG. 6 is a longitudinal sectional view of a solar cell structure according to a fourth preferred embodiment of the invention;

FIG. 7 is a longitudinal sectional view of a solar cell structure according to a fifth preferred embodiment of the invention;

FIG. 8 is a longitudinal sectional view of a solar cell structure according to a sixth preferred embodiment of the invention;

FIG. 9 is a longitudinal sectional view of a solar cell structure according to a seventh preferred embodiment of the invention;

FIG. 10 is a longitudinal sectional view of a solar cell structure according to an eighth preferred embodiment of the invention;

FIG. 11 is a longitudinal sectional view of a solar cell structure according to a ninth preferred embodiment of the invention;

FIG. 12 is a longitudinal sectional view of a solar cell structure according to a tenth preferred embodiment of the invention;

FIG. 13 is a longitudinal sectional view of a solar cell structure according to an eleventh preferred embodiment of the invention;

FIG. 14 is a longitudinal sectional view of a solar cell structure according to a twelfth preferred embodiment of the invention; and

FIG. 15 is a table of comparing the solar cell structure of the invention with the conventional solar cell in terms of power conversion efficiency increase.

### DETAILED DESCRIPTION OF THE INVENTION

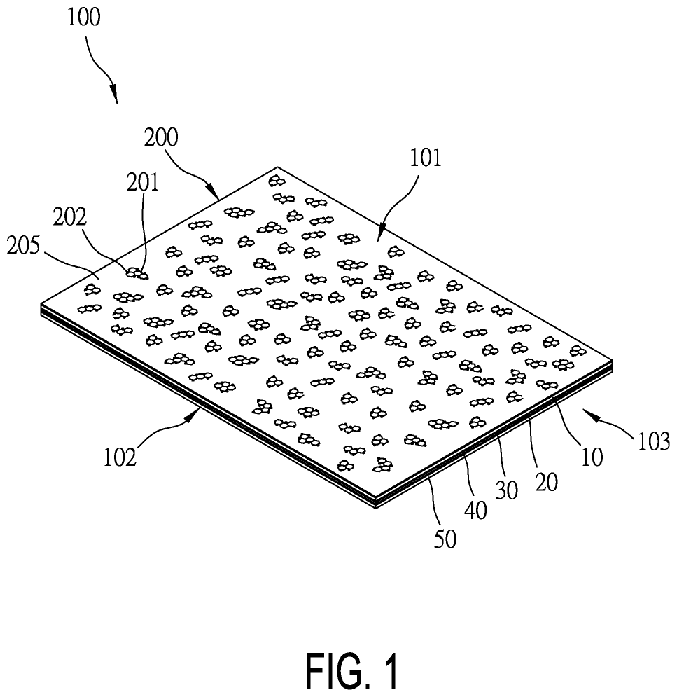

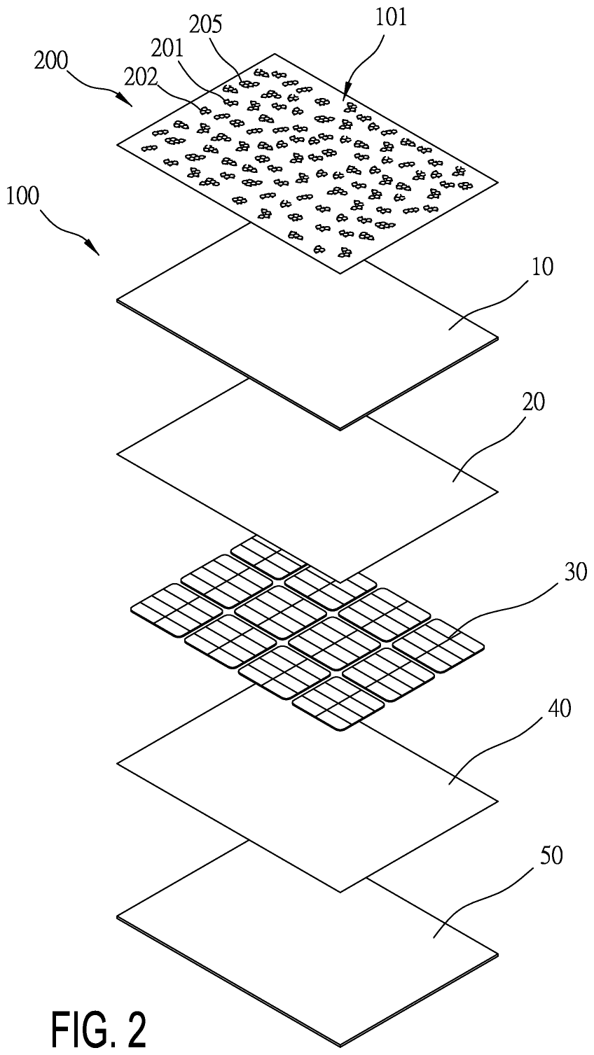

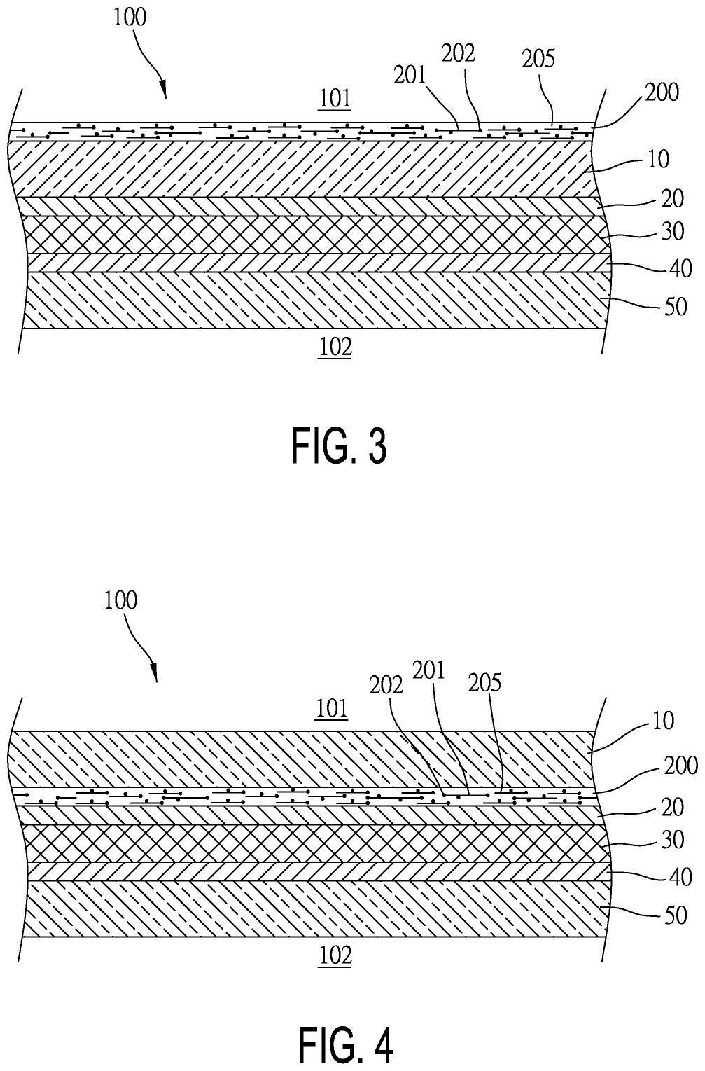

Referring to FIGS. 1 to 3, a solar cell structure 100 in accordance with a first preferred embodiment of the invention comprises a first surface 101 on a top, the first surface 101 including, from top to bottom, a power conversion efficiency increase layer 200, a glass layer 10, a first sealing layer 20, a photovoltaic effect junction 30, a second sealing layer 40, and a back layer 50; a second surface 102 on a bottom, and a peripheral surface 103 formed around the first surface 101 and the second surface 102.

The power conversion efficiency increase layer 200 is printed or coated on the glass layer 10 and includes a transparent material 205 and a plurality of conducting carbon materials 201 mixed with a plurality of fluorescent materials 202 in the transparent material 205. The conducting carbon materials 201 are selected from the group consisting of graphite, graphene, carbon nanotubes, carbon fiber, diamond, and any combinations thereof. The fluorescent materials 202 are selected from the group consisting of oxidation phosphor powder, sulfide phosphor powder, molybdate phosphor powder, rare earth ion phosphor powder, organic phosphor powder, and any combinations thereof. Both the conducting carbon materials 201 and the fluorescent materials 202 are micrometer scales or nanometer scales. The transparent material 205 is thermoplastic and selected from the group consisting of polyethylene (PE), polypropylene (PP), polystyrene (PS), polymethyl methacrylate (PMMA), polyvinyl chloride (PVC), nylon, polycarbonate (PC), ethylene-vinyl acetate copolymer (EVA), acrylic resin, and any combinations thereof. The conducting carbon materials 201 can increase absorption and collection efficiencies and increase conduction. For the conducting carbon materials 201 having graphene, it can increase photovoltaic effect (i.e., power conversion efficiency). The conducting carbon materials 201 can increase absorption and collection efficiencies. Specifically, the fluorescent materials 202 can absorb invisible light (e.g., infrared and ultraviolet) of the sunlight. Further, the fluorescent materials 202 can radiate the absorbed invisible light as visible light. This converts heat into light. The transparent material 205 radiates the visible light to the photovoltaic effect junction 30, thereby greatly increasing the power conversion efficiency.

In other embodiments, the power conversion efficiency increase layer 200 further comprises germanium compound powder and titanium compound powder for further increasing the power conversion efficiency.

The power conversion efficiency increase layer 200 comprises 1.5 wt % to 3.5 wt % of the f conducting carbon materials 201 and 0.005 wt % to 0.025 wt % of the fluorescent materials 202.

The conducting carbon materials 201 can release radiation in the form of heat to the atmosphere so that temperature of the solar cell structure 100 may decrease 10 to 15° C. Thus, the useful life of the solar cell structure 100 can be increased.

Referring to FIG. 4, a solar cell structure in accordance with a second preferred embodiment of the invention is shown. The characteristics of the second preferred embodiment are substantially the same as that of the first preferred embodiment except the following: the power conversion efficiency increase layer 200 is disposed between the glass layer 10 and the first sealing layer 20 so that the solar cell structure can be flexible.

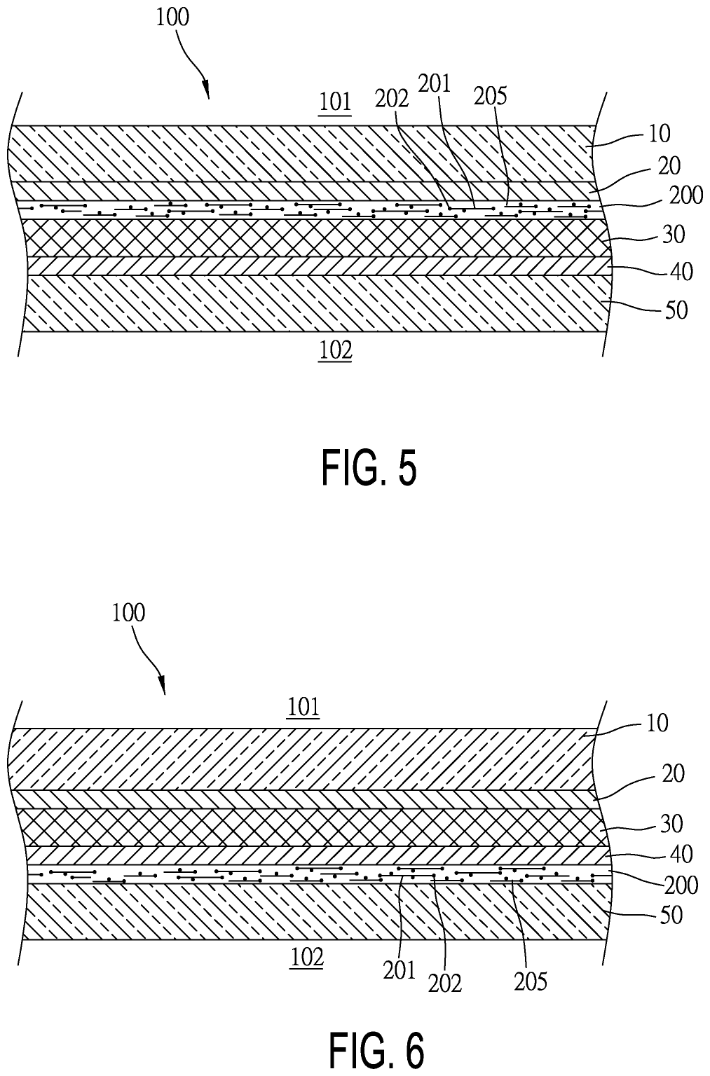

Referring to FIG. 5, a solar cell structure in accordance with a third preferred embodiment of the invention is shown. The characteristics of the third preferred embodiment are substantially the same as that of the second preferred embodiment except the following: the first sealing layer 20 is disposed between the glass layer 10 and the power conversion efficiency increase layer 200. Further, the power conversion efficiency increase layer 200 is configured to have an increased depth so that the solar cell structure is configured to serve as a window type solar cell structure and the power conversion efficiency increase layer 200 serves as a window.

Referring to FIG. 6, a solar cell structure in accordance with a fourth preferred embodiment of the invention is shown. The characteristics of the fourth preferred embodiment are substantially the same as that of the third preferred embodiment except the following: the second sealing layer 40 is disposed between the photovoltaic effect junction 30 and the power conversion efficiency increase layer 200.

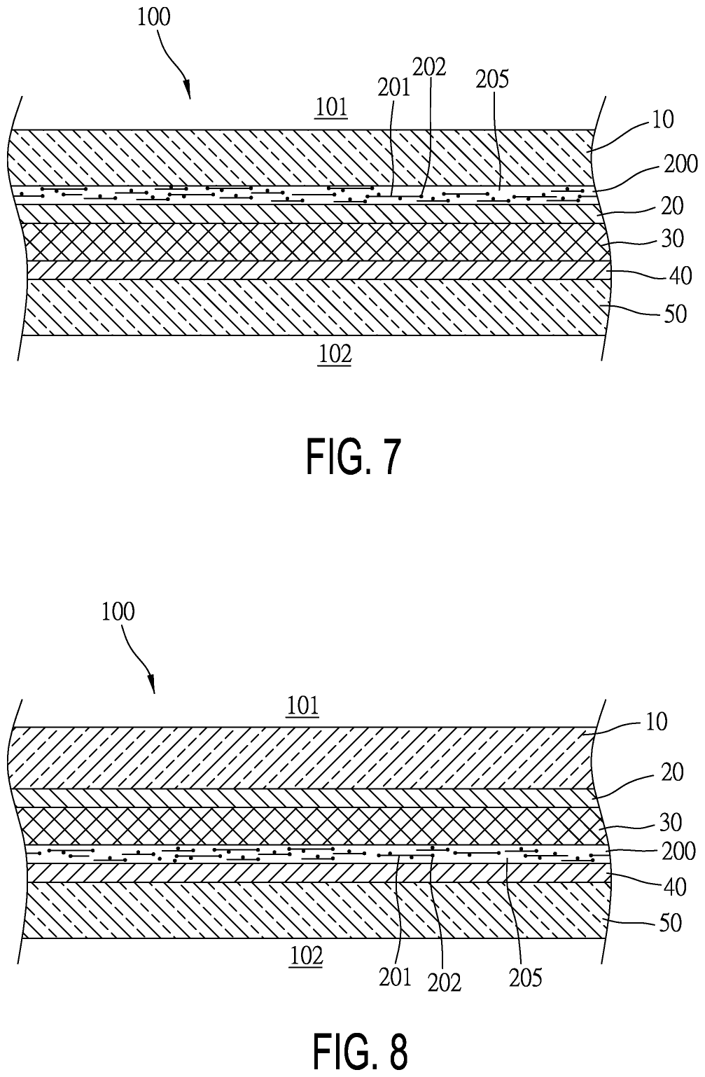

Referring to FIG. 7, a solar cell structure in accordance with a fifth preferred embodiment of the invention is shown. The characteristics of the fifth preferred embodiment are substantially the same as that of the second preferred embodiment except the following: the plurality of fluorescent materials 202 are mixed with the plurality of conducting carbon materials 201 in the transparent material 205.

Referring to FIG. 8, a solar cell structure in accordance with a sixth preferred embodiment of the invention is shown. The characteristics of the sixth preferred embodiment are substantially the same as that of the fifth preferred embodiment except the following: the photovoltaic effect junction 30 is disposed between the first sealing layer 20 and the power conversion efficiency increase layer 200.

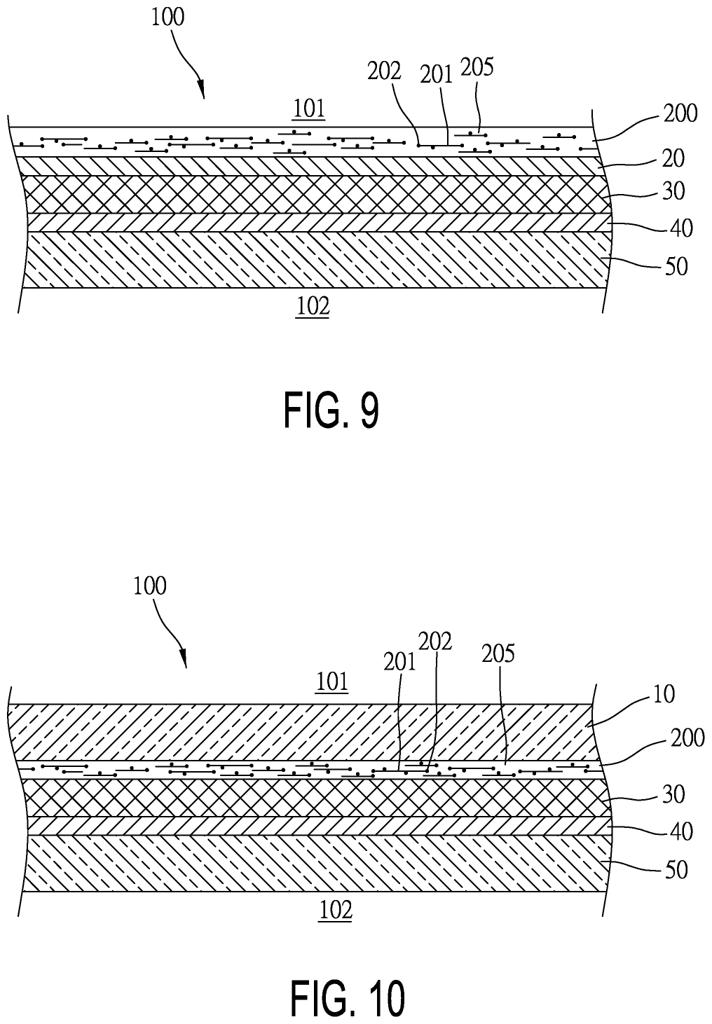

Referring to FIG. 9, a solar cell structure in accordance with a seventh preferred embodiment of the invention is shown. The characteristics of the seventh preferred embodiment are substantially the same as that of the fifth preferred embodiment except the following: the glass layer 10 is removed.

Referring to FIG. 10, a solar cell structure in accordance with an eighth preferred embodiment of the invention is shown. The characteristics of the eighth preferred embodiment are substantially the same as that of the second preferred embodiment except the following: the first sealing layer 20 is removed.

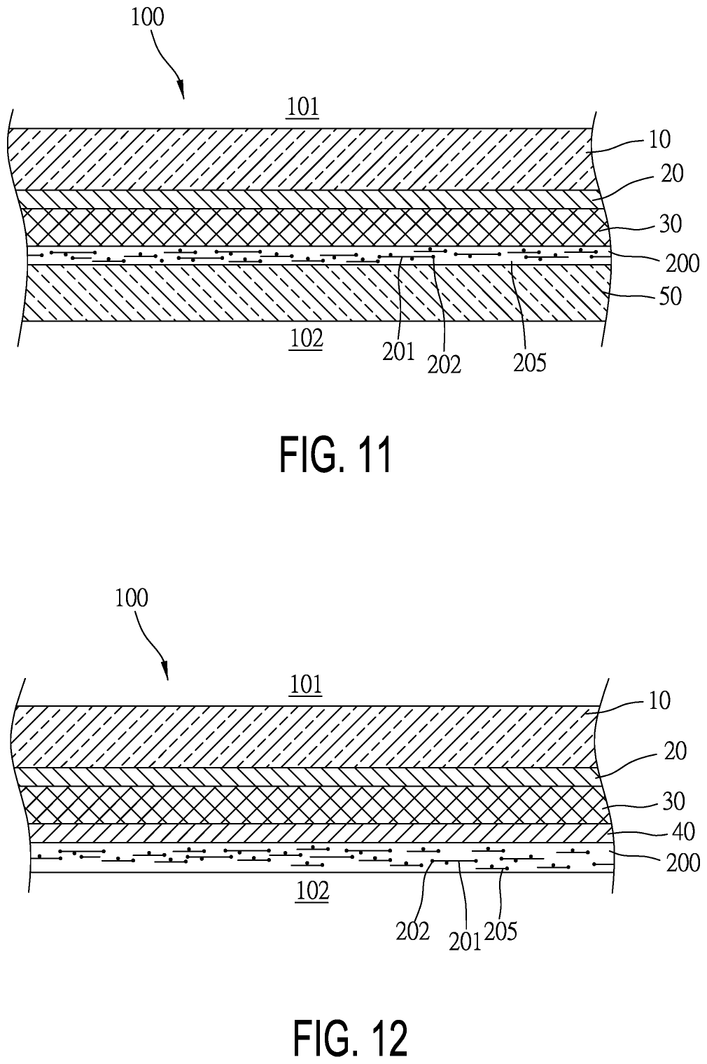

Referring to FIG. 11, a solar cell structure in accordance with a ninth preferred embodiment of the invention is shown. The characteristics of the ninth preferred embodiment are substantially the same as that of the sixth preferred embodiment except the following: the second sealing layer 40 is removed.

Referring to FIG. 12, a solar cell structure in accordance with a tenth preferred embodiment of the invention is shown. The characteristics of the tenth preferred embodiment are substantially the same as that of the fourth preferred embodiment except the following: the back layer 50 is removed.

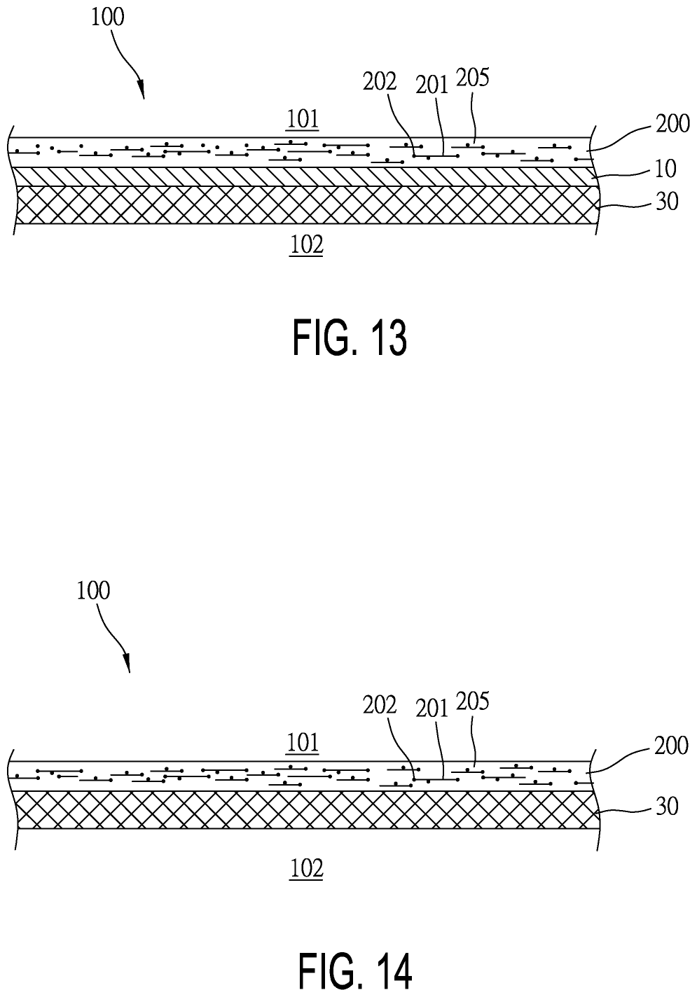

Referring to FIG. 13, a solar cell structure in accordance with an eleventh preferred embodiment of the invention is shown. The characteristics of the eleventh preferred embodiment are as below. Only the power conversion efficiency increase layer 200, the glass layer 10 and the photovoltaic effect junction 30 are provided and the glass layer 10 is disposed between the power conversion efficiency increase layer 200 and the photovoltaic effect junction 30.

Referring to FIG. 14, a solar cell structure in accordance with a twelfth preferred embodiment of the invention is shown. The characteristics of the twelfth preferred embodiment are as below. Only the power conversion efficiency increase layer 200 and the photovoltaic effect junction 30 are provided and the power conversion efficiency increase layer 200 is disposed on the photovoltaic effect junction 30.

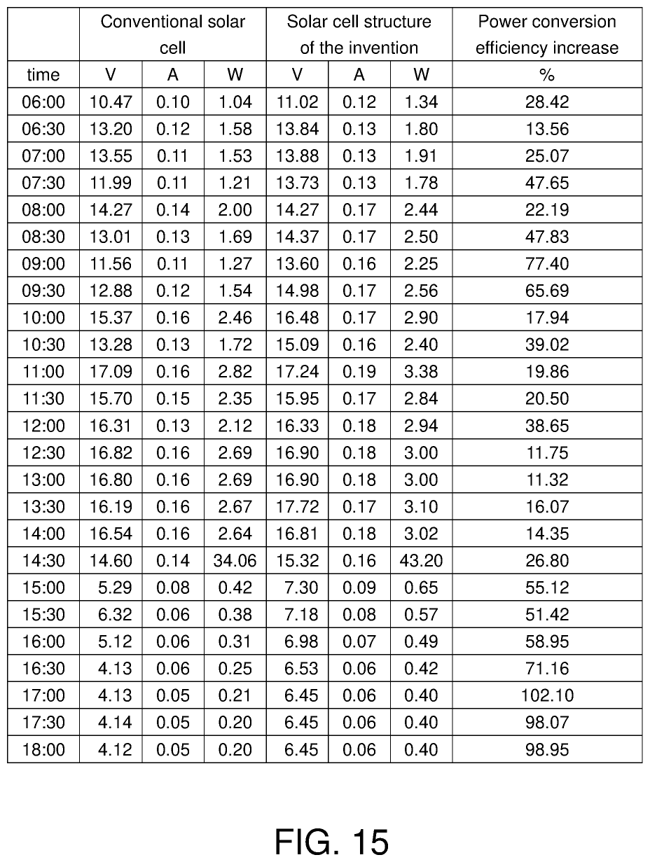

Referring to FIG. 15, it is a table of comparing the solar cell structure 100 of the invention with the conventional solar cell in terms of power conversion efficiency increase.

Data shown in FIG. 15 is obtained from an experiment having the following conditions: solar cell area: 105×54 cm²; power: 120 W; resistor: 20 W, 100Ω; time: from 6 AM to 6 PM. It is shown that the power conversion efficiency of the solar cell structure 100 of the invention is increased greatly in comparison with the conventional solar cell in term of voltage (V), current (A), and power (W).

While the invention has been described in terms of preferred embodiments, those skilled in the art will recognize that the invention can be practiced with modifications within the spirit and scope of the appended claims.

What is claimed is:

1. A solar cell structure, comprising:
a first surface on a top, the first surface including, from top to bottom, a power conversion efficiency increase layer, a glass layer, a first sealing layer, a photovoltaic effect junction, a second sealing layer, and a back layer;
a second surface on a bottom; and
a peripheral surface formed around the first surface and the second surface;
wherein the power conversion efficiency increase layer includes a transparent material, a plurality of fluorescent materials in the transparent material, and a plurality of conducting carbon materials mixed with the plurality of fluorescent materials;
wherein the fluorescent materials are micrometer scales or nanometer scales; and
wherein the transparent material is thermoplastic.

2. The solar cell structure of claim 1, wherein the power conversion efficiency increase layer is printed or coated on the glass layer.

3. The solar cell structure of claim 1, wherein the conducting carbon materials are selected from the group consisting of graphite, graphene, carbon nanotubes, carbon fiber, diamond, and any combinations thereof.

4. The solar cell structure of claim 1, wherein the fluorescent materials are selected from the group consisting of oxidation phosphor powder, sulfide phosphor powder, molybdate phosphor powder, rare earth ion phosphor powder, organic phosphor powder, and any combinations thereof.

5. The solar cell structure of claim 1, wherein the transparent material is selected from the group consisting of polyethylene (PE), polypropylene (PP), polystyrene (PS), polymethyl methacrylate (PMMA), polyvinyl chloride (PVC), nylon, polycarbonate (PC), ethylene-vinyl acetate copolymer (EVA), acrylic resin, and any combinations thereof.

6. The solar cell structure of claim 1, wherein the power conversion efficiency increase layer is disposed between the glass layer and the first sealing layer so that the solar cell structure is configured to flex.

7. The solar cell structure of claim 1, wherein the power conversion efficiency increase layer is configured to have an increased depth so that the solar cell structure is configured to serve as a window type solar cell structure and the power conversion efficiency increase layer serves as a window.
